(19) United States
(12) Patent Application Publication
(10) Pub. No.: US 2003/0178715 A1
(43) Pub. Date: Sep. 25, 2003

(54) Method for stacking chips within a multichip module package

(75) Inventors: Keith K. Sturcken, Nokesville, VA (US); Sheila J. Konecke, Leesburg, VA (US); Santos Nazario-Camacho, Culpepper, VA (US)

Correspondence Address: BRACEWELL & PATTERSON, L.L.P., Intellectual Property Law, P.O. Box 969, Austin, TX, 78767-0969, US

(73) Assignee: BAE Systems

(21) Appl. No.: 10/102,324

(22) Filed: Mar. 20, 2002

(51) Int. Cl. H01L 23/52

(52) U.S. Cl. 257/686; 257/777; 438/109

(57) ABSTRACT

A method for stacking chips within a multichip module package is disclosed. A first chip is bonded to a substrate. A passivation layer is then deposited on a top surface of the first chip. After a first adhesive layer has been deposited on top of the passivation layer, an interposer is placed on the adhesive layer. Next, a second adhesive layer is deposited on the interposer. Finally, a second chip is bonded to the interposer via the second adhesive layer.

### BACKGROUND OF THE INVENTION

1. Technical Field

The present invention relates to integrated circuit device packaging in general, and in particular to multichip module packages. Still more particularly, the present invention relates to a multichip module package having a stacked chip arrangement.

2. Description of the Related Art

When it comes to integrated circuit device packaging, it is always desirable

and sometimes imperative to have a relatively high device packaging density. Device packaging density can be defined as the number of devices per unit package volume. To such end, multichip modules (MCMs) packages are increasingly attractive for a variety of reasons. For example, MCM packages, which contain more than one chip per package, decrease the interconnection length between chips, thereby reducing signal delays and access times. In addition, MCM packages can also improve system operational speed that is previously limited by long connection traces on a printed circuit board.

The most common MCM package is the “side-by-side” MCM package in which two or more chips are mounted next to each other (i.e., side-by-side to each other) on a common substrate. Interconnections among chips and conductive traces on the common substrate are electrically made via bond wires. Side-by-side MCM packages, however, suffer from low package efficiency because the area of common substrate also increases as the number of chips mounted thereon increases. Three-dimensional device packaging in the form of chip stacking provides a solution to the above-mentioned problem. Chip stacking, which is accomplished by stacking chips on top of each other, is the most effective method of packaging integrated circuit device at a device level. Unfortunately, the physical designs and performance requirements of most chips are not conducive to chip stacking. Thus, even though chip stacking is very appealing in terms of the high device packaging density it can provide, chip stacking is not a well-received method in the semiconductor industry for packaging integrated circuit devices. Consequently, it is desirable to provide an improved method for stacking chips within a MCM package.

### SUMMARY OF THE INVENTION

In accordance with a preferred embodiment of the present invention, a first chip is bonded to a substrate. A passivation layer is then deposited on a top surface of the first chip. After a first adhesive layer has been deposited on top of the passivation layer, an interposer is placed on the adhesive layer. Next, a second adhesive layer is deposited on the interposer. Finally, a second chip is bonded to the interposer via the second adhesive layer.

All objects, features, and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is a side view of a multichip module, in accordance with a preferred embodiment of the present invention; and

FIG. 2 is a high-level process flow diagram of a method for stacking chip in a multichip module, in accordance with the preferred embodiment of the present invention.

### DETAILED DESCRIPTION OF A PREFERRED EMBODIMENT

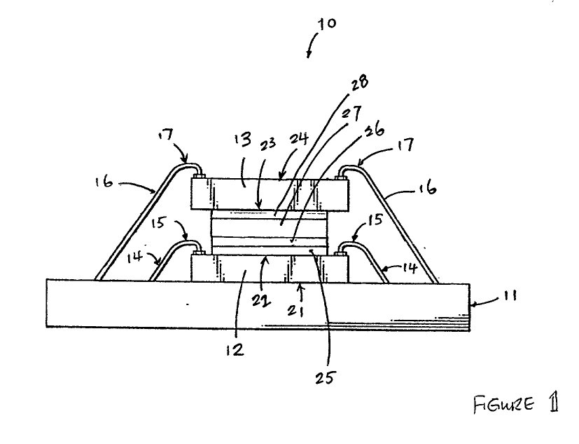

Referring now to the drawings and, in particular, to FIG. 1, there is depicted a side view of a multichip module (MCM), in accordance with the preferred embodiment of the present invention. As shown, a MCM 10 includes a substrate 11, a first chip 12 and a second chip 13. First chip 12 includes a bondable surface 21 and an active surface 22. Bondable surface 21 is adhered to substrate 11 by means of an adhesive, such as an epoxy, from thermoplastic materials, tapes, tapes coated with thermoplastic materials, etc. Active surface 22 includes an active circuit area, preferably in the center of first chip 12, and multiple bonding pads are located peripheral to the active circuit area. Similarly, second chip 13 includes a bondable surface 23 and an active surface 24. Active surface 24 also includes an active circuit area, preferably in the center of second chip 13, and multiple bonding pads are located peripheral to the active circuit area.

The active circuit area of first chip 12 is covered by a passivation layer 25. Preferably, the thickness of passivation layer 25 is approximately 25-30 microns. An adhesive layer 26 is interposed between and connects passivation layer 25 and an interposer 27. Preferably, adhesive layer 26 has a thickness of approximately 25-30 microns.

Interposer 27 is preferably made of a material similar in properties to first chip 12 and second chip 13 in order to avoid thermal expansion mismatch over temperature variations. For example, if first chip 12 and second chip 13 are made of bulk silicon, interposer 27 should also be made of silicon. Interposer 27 must be of a planar dimension to allow clearance and access to the bond pads along the edges of first chip 12. Interposer 27 also serves as a pedestal for supporting second chip 13. Thus, interposer 27 should have a thickness sufficient to provide clearance for bond wire loop height off the bond pads of first chip 12. As an example, interposer 27 has a preferable thickness of approximately 225-275 microns.

An adhesive layer 28 is interposed between and connects interposer 27 and bondable surface 23 of second chip 13. Preferably, adhesive layer 28 has a thickness of approximately 30-40 microns.

Several bond wires 14 are bonded to and between respective bonding pads on first chip 12 and substrate 11. Bond wires 14 includes outwardly projecting loops 15 having a defined loop height between active circuit surface 22 and the maximum extent of loops 15. The thickness of interposer 27 should be greater than the loop height to displace bondable surface 23 of second chip 13 in a non-contacting relationship about and with respect to bond wires 14. Similarly, several bond wires 16 are bonded to and between respective bonding pads on second chip 12 and substrate 11. Bond wires 16 includes outwardly projecting loops 17 having a defined loop height between active circuit surface 22 and the maximum extent of loops 17.

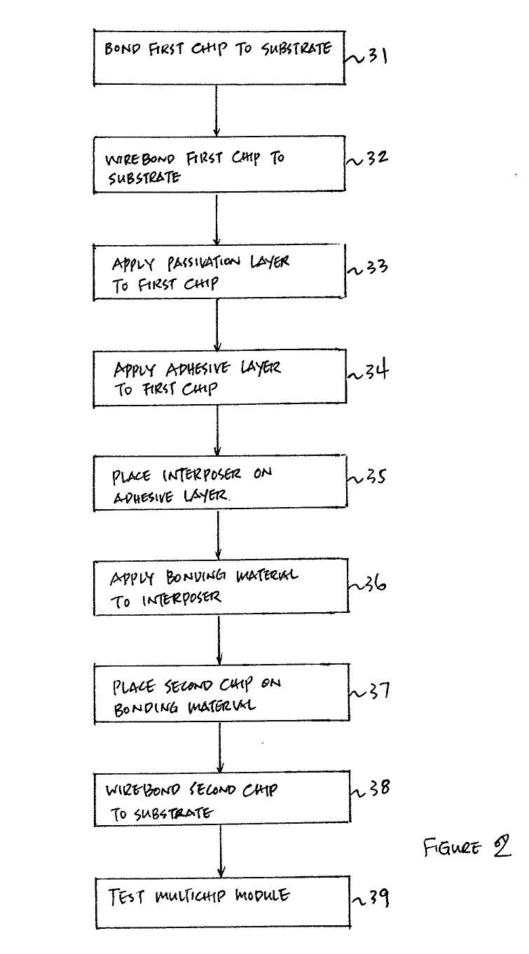

With reference now to FIG. 2, there is illustrated a high-level process flow diagram of a method for stacking chips within a MCM, such as MCM 10 from FIG. 1, in accordance with the preferred embodiment of the present invention. First, a first chip is bonded onto a substrate using standard bonding materials, as shown in block 31. The first chip is then wire-bonded, as depicted in block 32, and tested for functionality. A preservation layer, for example, polyimide, is applied to the top surface of the first chip, as shown in block 33, to provide protection to the active circuit area of the first chip. After the preservation layer has been cured, a layer of adhesive material is then applied to the passivation layer on the top surface of the first chip, as shown in block 34. The layer of adhesive material is preferably applied in a pattern that is appropriate for subsequent bonding of an interposer. Next, an interposer is placed on the layer of adhesive material, as depicted in block 35, in order to bond with the top surface of first chip.

After applying a layer of bonding material on the top surface of the interposer, as shown in block 36, a second chip is then be added to the top surface of the interposer, as depicted in block 37. The bonding material is preferably a low-temperature thermoplastic that is re-workable such that the second chip can easily be removed from the interposer if the second chip turns out to be defective. After the second chip has been mounted onto the interposer, the second chip is then wire-bonded, as shown in block 38, and tested for functionality. The entire MCM can then be completed with appropriate testings, as depicted in block 39.

As has been described, the present invention provides an improved method for stacking a second chip on top of a first chip within a MCM package. The key features of the present invention include the application of a protective passivation layer to the active circuit area of the first chip (i.e. the bottom chip), the use of an interposer having a similar material as the first and second chips, and the use of a re-workable adhesive to bond the second chip (i.e., the top chip) to the interposer so, if necessary, the second chip can be removed without affecting the first chip.

Although only two chips are shown to be stacked within a MCM in the present disclosure, it is possible to stack more than two chips using the same methodology to achieve a stack of three or more chips within a single MCM.

While the invention has been particularly shown and described with reference to a preferred embodiment, it will be understood by those skilled in the art that various changes in form and detail may be made therein without departing from the spirit and scope of the invention.

What is claimed is:

1. A method for stacking chips within a multichip module package, said method comprising:
bonding a first chip to a substrate;
depositing a passivation layer on a top surface of said first chip;
depositing a first adhesive layer on said passivation layer;
placing an interposer on said adhesive layer;
depositing a second adhesive layer on said interposer; and
bonding a second chip to said interposer via said second adhesive layer.

2. The method of claim 1, wherein said method further includes wirebonding said first chip to said substrate.

3. The method of claim 2, wherein said method further includes wirebonding said second chip to said substrate.

4. The method of claim 1, wherein said method further includes testing said multichip module.

5. The method of claim 1, wherein said passivation layer has a thickness of approximately 25-30 microns.

6. The method of claim 1, wherein said first adhesive layer has a thickness of approximately 25-30 microns.

7. The method of claim 1, wherein said interposer has a thickness of approximately 225-275 microns.

8. The method of claim 1, wherein said second adhesive layer has a thickness of approximately 30-40 microns.

9. The method of claim 1, wherein said first chip, said second chip, and said interposer are made of silicon.

10. The method of claim 1, wherein said second adhesive layer is low-temperature thermoplastic.

11. A multichip module package, comprising:
a first chip bonded to a substrate;
a passivation layer on a top surface of said first chip;
an interposer;
a first adhesive layer interposed between said interposer and said passivation layer;
a second chip; and
a second adhesive layer interposed between said second chip and said interposer.

12. The multichip module package of claim 11, wherein said multichip module package further includes wirebonds from said first chip to said substrate.

13. The multichip module package of claim 12, wherein said multichip module package further includes wirebonds from said second chip to said substrate.

14. The multichip module package of claim 11, wherein said passivation layer has a thickness of approximately 25-30 microns.

15. The multichip module package of claim 11, wherein said first adhesive layer has a thickness of approximately 25-30 microns.

16. The multichip module package of claim 11, wherein said interposer has a thickness of approximately 225-275 microns.

17. The multichip module package of claim 11, wherein said second adhesive layer has a thickness of approximately 30-40 microns.

18. The multichip module package of claim 11, wherein said first chip, said second chip, and said interposer are made of silicon.

19. The multichip module package of claim 1, wherein said second adhesive layer is low-temperature thermoplastic.
